(19) United States
(12) Patent Application Publication
(10) Pub. No.: US 2025/0219375 A1
(43) Pub. Date: Jul. 3, 2025

(54) ELECTRICAL JUNCTION BOX

(71) Applicant: YAZAKI CORPORATION, Tokyo (JP)

(72) Inventors: Syuji Kimura, Makinohara-shi (JP); Sadaharu Okuda, Makinohara-shi (JP)

(21) Appl. No.: 19/084,702

(22) Filed: Mar. 19, 2025

Related U.S. Application Data
(63) Continuation of application No. PCT/JP2024/000290, filed on Jan. 10, 2024.

(30) Foreign Application Priority Data
Feb. 14, 2023 (JP) 2023-020605

(51) Int. Cl. H02G 3/16; B60R 16/023; H02G 3/08

(52) U.S. Cl. CPC H02G 3/16; H02G 3/086; B60R 16/0238

(57) ABSTRACT

An electrical junction box includes: a substrate; a terminal holder fixed to the substrate; each of terminals that has a first connection portion connected to a partner terminal, is held by the terminal holder in a state where the first connection portion is protruded, and is connected to the substrate; a housing that accommodates the substrate and the terminal holder; and a conductor unit fixed to the terminal holder or the housing, and the conductor unit includes: a first conductor that has a frame portion and is fixed to the terminal holder or the housing; and a plurality of second conductors each having a joint portion joined to the frame portion and a second connection portion connected to a partner terminal.

### CROSS-REFERENCE TO RELATED APPLICATION

This application is a continuation application of International Application No. PCT/JP2024/000290 filed on Jan. 10, 2024 which claims the benefit of priority from Japanese Patent Application No. 2023-020605 filed on Feb. 14, 2023 and designating the U.S., the entire contents of which are incorporated herein by reference.

### BACKGROUND OF THE INVENTION

### 1. Field of the Invention

The present invention relates to an electrical junction box.

### 2. Description of the Related Art

Conventionally, there is a press-molded connector. JP 2007-087 710 A discloses a connector including a female connector portion and four connection terminals that are press-molded plate-like bodies, are insert-molded to the female connector portion, and are for electrical connection to the outside.

In an electrical junction box having a plurality of terminals, it is desirable to be able to improve a degree of freedom in design in a case where the terminals are arranged. For example, it is preferable that the design can be easily changed according to arrangement of terminals of a connection partner.

### SUMMARY OF THE INVENTION

An object of the present invention is to provide an electrical junction box capable of improving a degree of freedom in design in arrangement of terminals.

In order to achieve the above mentioned object, an electrical junction box according to one aspect of the present invention includes: a substrate; a terminal holder fixed to the substrate; each of terminals that has a first connection portion connected to a partner terminal, is held by the terminal holder in a state where the first connection portion is protruded, and is connected to the substrate; a housing that accommodates the substrate and the terminal holder; and a conductor unit fixed to the terminal holder or the housing, wherein the conductor unit includes: a first conductor that has a frame portion and is fixed to the terminal holder or the housing; and a plurality of second conductors each having a joint portion joined to the frame portion and a second connection portion connected to a partner terminal.

The above and other objects, features, advantages and technical and industrial significance of this invention will be better understood by reading the following detailed description of presently preferred embodiments of the invention, when considered in connection with the accompanying drawings.

### BRIEF DESCRIPTION OF THE DRAWINGS

FIG. 1 is a perspective view of an electrical junction box according to an embodiment;

FIG. 2 is a cross-sectional view of the electrical junction box according to the embodiment;

FIG. 3 is a perspective view of a housing according to the embodiment;

FIG. 4 is a perspective view of a terminal holder according to the embodiment;

FIG. 5 is a perspective view of the terminal holder that holds terminals;

FIG. 6 is a perspective view of a conductor unit according to the embodiment;

FIG. 7 is a development view of a second conductor according to the embodiment;

FIG. 8 is a plan view of the conductor unit according to the embodiment;

FIG. 9 is a plan view of the conductor unit assembled to the terminal holder;

FIG. 10 is a cross-sectional view of the electrical junction box according to a first modification of the embodiment; and

FIG. 11 is a perspective view of a tuning fork terminal and a substrate connection portion according to the first modification of the embodiment.

### DETAILED DESCRIPTION OF THE PREFERRED EMBODIMENTS

Hereinafter, an electrical junction box according to an embodiment of the present invention will be described in detail with reference to the drawings. Note that this invention is not limited by this embodiment. Furthermore, components in the following embodiment include those that can be easily assumed by those skilled in the art or those that are substantially the same.

### Embodiment

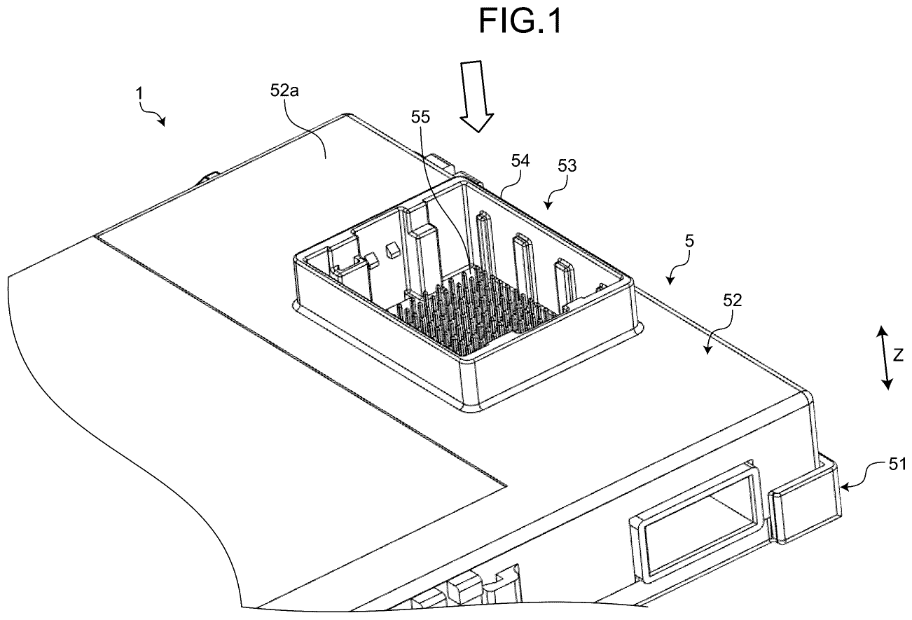

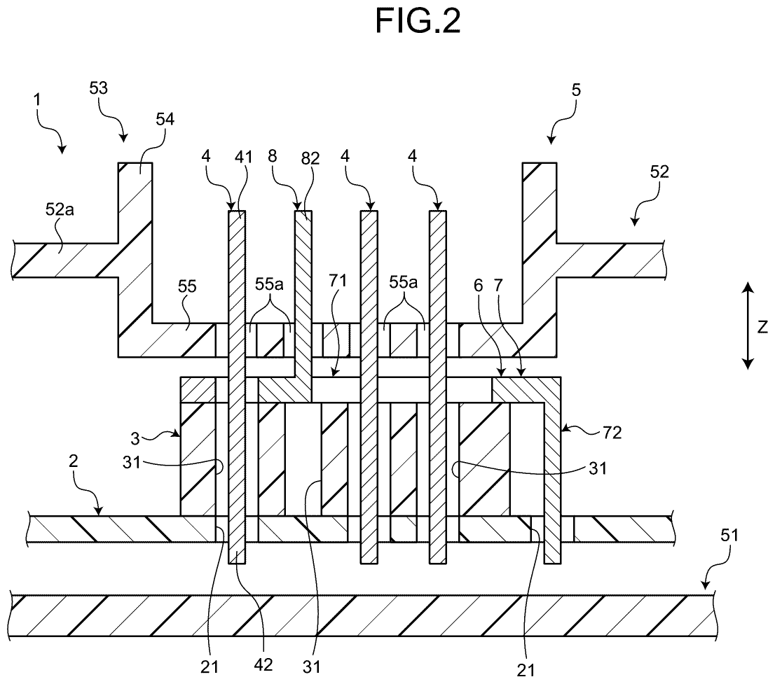

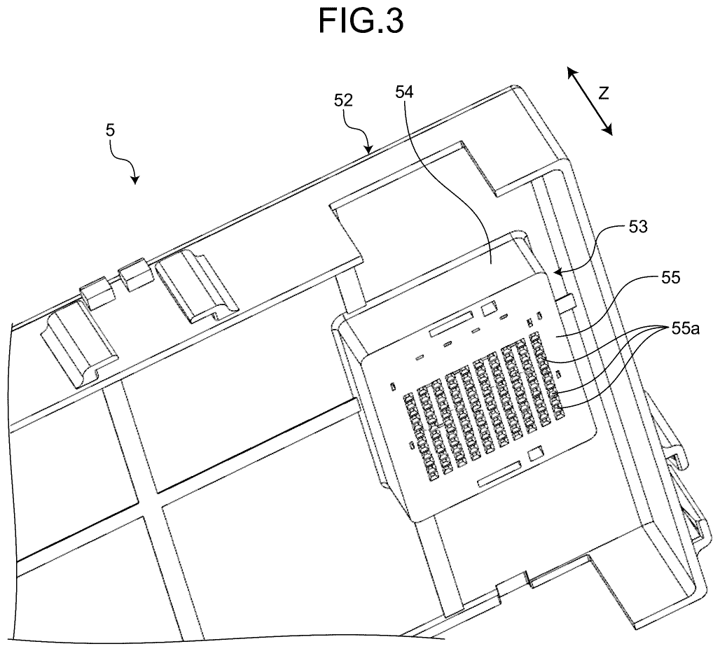

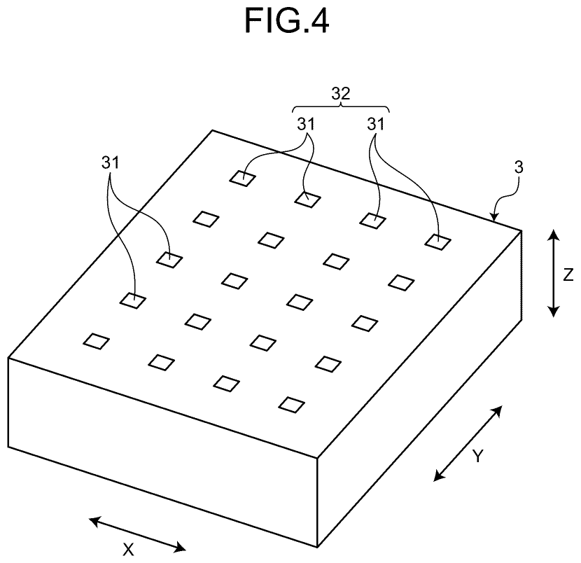

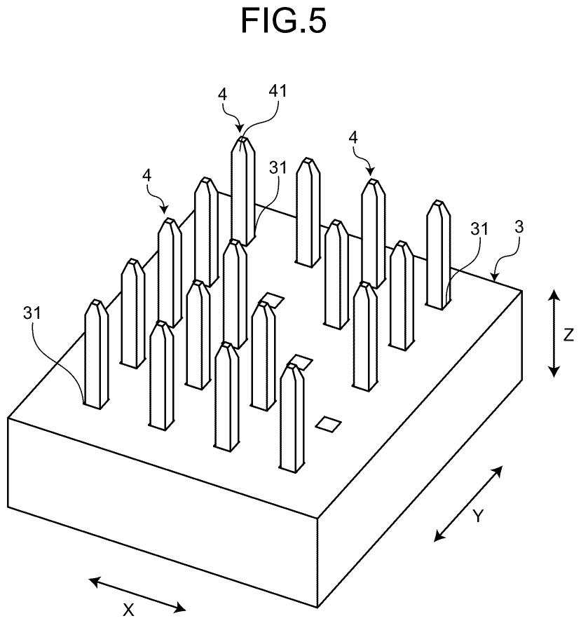

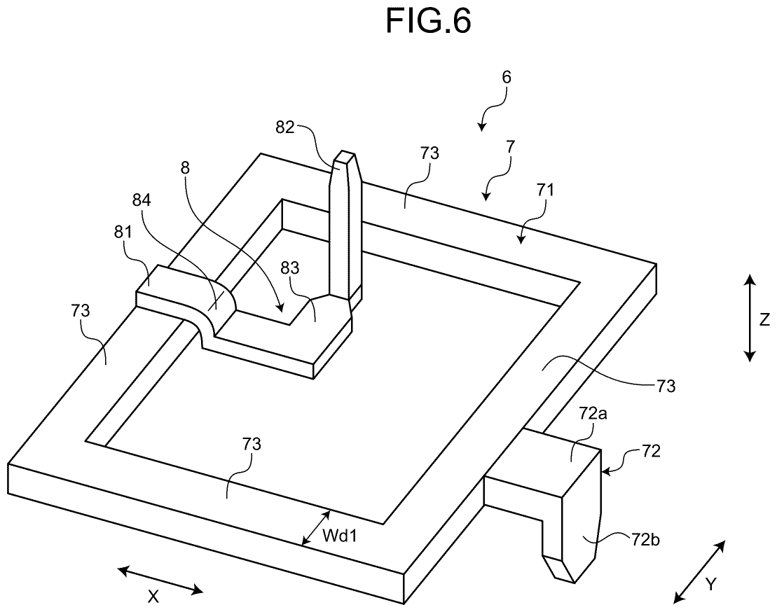

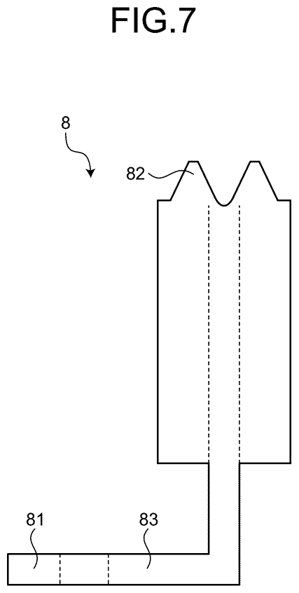

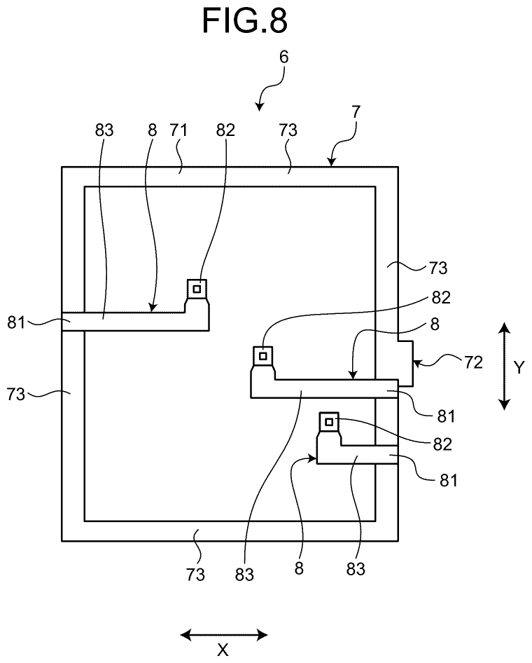

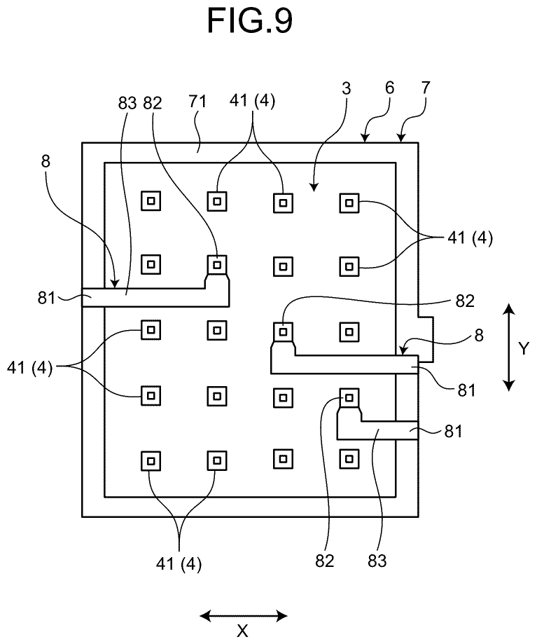

The embodiment will be described with reference to FIGS. 1 to 9. The present embodiment relates to the electrical junction box. FIG. 1 is a perspective view of the electrical junction box according to the embodiment, FIG. 2 is a cross-sectional view of the electrical junction box according to the embodiment, FIG. 3 is a perspective view of a housing according to the embodiment, FIG. 4 is a perspective view of a terminal holder according to the embodiment, FIG. 5 is a perspective view of the terminal holder that holds terminals, FIG. 6 is a perspective view of a conductor unit according to the embodiment, FIG. 7 is a development view of a second conductor according to the embodiment, FIG. 8 is a plan view of the conductor unit according to the embodiment, and FIG. 9 is a plan view of the conductor unit assembled to the terminal holder.

As illustrated in FIGS. 1 and 2, an electrical junction box 1 of the present embodiment includes a substrate 2, a terminal holder 3, terminals 4, a housing 5, and a conductor unit 6. The electrical junction box 1 is mounted on a vehicle such as an automobile, for example. The electrical junction box 1 may include, for example, an electronic control unit (ECU) that controls a device mounted on the vehicle, and the electronic control unit may be a zone ECU. The substrate 2 is, for example, a rigid printed circuit board (PCB).

The housing 5 illustrated in FIG. 1 has a substantially rectangular parallelepiped shape, and includes a main body 51 and a cover 52. The main body 51 and the cover 52 are molded using, for example, insulating synthetic resin. The housing 5 accommodates the substrate 2, the terminal holder 3, the terminals 4, and the conductor unit 6. The main body 51 is a flat plate-shaped member and holds the substrate 2. As illustrated in FIG. 2, the terminal holder 3, the terminals 4, and the conductor unit 6 are assembled to the substrate 2. The cover 52 has a bottomed square tube shape. The cover 52 engages with the main body 51 to cover the substrate 2, the terminal holder 3, the terminals 4, and the conductor unit 6.

As illustrated in FIG. 1, the cover 52 has a fitting portion 53 to be fitted to a partner connector. The fitting portion 53 is arranged at a position facing the terminal holder 3. In the present specification, a direction in which the housing 5 and the partner connector are fitted to each other is referred to as a fitting direction Z. The fitting direction Z is a direction orthogonal to the substrate 2. The main body 51 and the cover 52 are engaged with each other along the fitting direction Z.

The fitting portion 53 has a tube portion 54 and a bottom wall 55. The tube portion 54 has a square tube shape and protrudes from a top surface 52a of the cover 52 in the fitting direction Z. The bottom wall 55 is a wall portion that closes the tube portion 54, and faces the terminal holder 3 in the fitting direction Z. As illustrated in FIGS. 2 and 3, the bottom wall 55 is provided with a plurality of through holes 55a. The plurality of through holes 55a is arranged such that a first connection portion 41 of the terminal 4 and a second connection portion 82 of the conductor unit 6 can be inserted thereinto. The through holes 55a of the present embodiment are arranged in a lattice shape.

As illustrated in FIG. 4, the terminal holder 3 of the present embodiment has a rectangular parallelepiped shape. The terminal holder 3 is molded using, for example, insulating synthetic resin. The terminal holder 3 has a plurality of through holes 31. The through holes 31 of the present embodiment are arranged in a lattice shape. That is, the plurality of through holes 31 is arrayed in two directions orthogonal to each other. In the present specification, one direction in which the through holes 31 are arrayed is referred to as a “first direction X”, and the other one direction is referred to as a “second direction Y”. The second direction Y is orthogonal to the first direction X. Furthermore, both the first direction X and the second direction Y are orthogonal to the fitting direction Z.

The terminal holder 3 is provided with a plurality of rows 32 of the through holes 31. The plurality of rows 32 is arranged at equal intervals in the second direction Y. Each of the rows 32 has the plurality of through holes 31 arranged at equal intervals in the first direction X. The exemplified terminal holder 3 has the five rows 32. Each of the rows 32 has the four through holes 31. Note that the number of the through holes 31 included in one of the rows 32 and the number of the rows 32 included in the terminal holder 3 are optional.

As illustrated in FIGS. 2 and 5, the terminal 4 has the first connection portion 41 and a substrate connection portion 42. The exemplified terminal 4 is a male terminal and has a square tube shape or a square column shape. As illustrated in FIG. 5, the terminal 4 is inserted into the through hole 31 of the terminal holder 3 and held by the terminal holder 3. The terminal holder 3 holds the terminal 4 such that the first connection portion 41 and the substrate connection portion 42 protrude from the terminal holder 3. The first connection portion 41 protrudes from the through hole 31 to one side in the fitting direction Z. The substrate connection portion 42 protrudes from the through hole 31 to the other side in the fitting direction Z. The substrate connection portion 42 is inserted into a through hole 21 of the substrate 2 and soldered to a circuit of the substrate 2.

As illustrated in FIG. 5, the terminals 4 are inserted into a part of the through holes 31 among the plurality of through holes 31. The other part of the through holes 31 are left hollow without any of the terminals 4 being inserted therein. The second connection portions 82 of second conductors 8 to be described later are positioned in the other part of the through holes 31.

As illustrated in FIG. 6, the conductor unit 6 includes a first conductor 7 and the second conductor 8. The first conductor 7 and the second conductor 8 are formed of conductive metal. The first conductor 7 and the second conductor 8 are formed by, for example, pressing a metal plate.

The first conductor 7 has a frame portion 71 and a substrate connection portion 72. The frame portion 71 is formed in a frame shape. The frame portion 71 exemplified in FIG. 6 has a rectangular frame shape. The frame portion 71 has four sides 73. The frame portion 71 may be closed or may be partially interrupted. For example, a cut may be provided in any one of the four sides 73. A width Wd1 of the side 73 may be uniform. In the frame portion 71 of the present embodiment, the four sides 73 have the same width Wd1.

The substrate connection portion 72 is a portion connected to the circuit of the substrate 2. The exemplified substrate connection portion 72 is bent in an L shape and has a proximal end portion 72a and a distal end portion 72b. The proximal end portion 72a is connected to an outer edge of the frame portion 71 and protrudes in a direction orthogonal to the fitting direction Z. The distal end portion 72b protrudes from the proximal end portion 72a in the fitting direction Z.

The second conductor 8 is joined to the frame portion 71 and is electrically connected to the frame portion 71. The second conductor 8 has a joint portion 81, the second connection portion 82, and a connector portion 83. The joint portion 81 is a portion joined to the frame portion 71 and has a flat plate shape. The second connection portion 82 is a portion connected to a partner terminal and has a tube shape or a rod shape. The connector portion 83 is a portion connecting the joint portion 81 and the second connection portion 82. The second conductor 8 has a bent portion 84 bent so as to bring the connector portion 83 into contact with the terminal holder 3. The bent portion 84 positions the connector portion 83 on the same surface as the frame portion 71.

FIG. 7 illustrates an example of a development view of the second conductor 8. The second connection portion 82 of the present embodiment is formed by bending a metal plate into a tube shape. The shape of the second connection portion 82 is, for example, a square tube shape similar to that of the first connection portion 41. A shape of the connector portion 83 is a shape that connects the joint portion 81 and the second connection portion 82 while bypassing the terminal 4. The shape of the connector portion 83 illustrated in FIG. 7 is an L shape.

FIG. 8 illustrates the conductor unit 6 corresponding to the arrangement of the terminals 4 illustrated in FIG. 5. The conductor unit 6 of FIG. 8 includes the three second conductors 8. The second conductor 8 can be joined to any of the four sides 73 of the frame portion 71. In the conductor unit 6 illustrated in FIG. 8, the two second conductors 8 are joined to the side 73 having the substrate connection portion 72. The other one second conductor 8 is joined to the side 73 facing the substrate connection portion 72. The joint portion 81 is joined to the frame portion 71 by welding or the like. Note that a method of joining the joint portion 81 to the frame portion 71 is not limited to the welding, and may be pressure welding or the like. The frame portion 71 is preferably provided with a mark for positioning the joint portion 81. The mark is, for example, a scribe line or a dot.

The conductor unit 6 is placed on the terminal holder 3 and fixed to the terminal holder 3. The conductor unit 6 may have an engagement portion that engages with the terminal holder 3. FIG. 9 illustrates the conductor unit 6 assembled to the terminal holder 3. The second conductor 8 is fixed to the frame portion 71 such that the first connection portions 41 and the second connection portions 82 are arranged in a lattice shape. The connector portion 83 of the second conductor 8 extends between the arrayed terminals 4. That is, the second conductor 8 is joined to the frame portion 71 such that the connector portion 83 is positioned in the middle of the two terminals 4 arranged side by side. As illustrated in FIG. 2, the second connection portion 82 is positioned on an extension line of the through hole 31. That is, in the conductor unit 6, the second connection portion 82 is positioned on the extension line of the through hole 31 into which the terminal 4 is not inserted.

The terminal holder 3 assembled with the conductor unit 6 is fixed to the substrate 2. When the terminal holder 3 is placed at a predetermined position on the substrate 2, the substrate connection portion 42 of the terminal 4 and the substrate connection portion 72 of the conductor unit 6 are inserted into the through holes 21 of the substrate 2. The terminal holder 3 may be fixed to the substrate 2 by a peg. The substrate connection portion 42 of the terminal 4 and the substrate connection portion 72 of the conductor unit 6 are soldered to the circuit of the substrate 2. The substrate 2 assembled with the terminal holder 3 is fixed to the main body 51 of the housing 5.

The second conductor 8 may be a male terminal for GND. In this case, the plurality of second conductors 8 as ground terminals are electrically connected to each other by the frame portion 71. The plurality of second conductors 8 is connected to the circuit of the substrate 2 via the substrate connection portion 72.

In the electrical junction box 1 of the present embodiment, the second connection portion 82 can be positioned in the optional through hole 31 of the terminal holder 3. The connector portion 83 is bent so as not to interfere with the terminal 4, and positions the second connection portion 82 on the extension line of the through hole 31. Positions of ground terminals of a partner connector varies depending on a vehicle and a specification. In the electrical junction box 1 of the present embodiment, since positions of the second connection portions 82 can be easily changed according to the partner connector, a degree of freedom in design is high, and cost reduction can be achieved. Furthermore, it is not necessary to provide a joint pattern for connecting the plurality of ground terminals on the substrate 2. Therefore, cost reduction of the substrate 2 and space saving of the substrate 2 can be achieved.

As described above, the electrical junction box 1 of the present embodiment includes the substrate 2, the terminal holder 3, the terminals 4, the housing 5, and the conductor unit 6. The terminal holder 3 is fixed to the substrate 2. The terminal 4 has the first connection portion 41 connected to a partner terminal. The terminals 4 are held by the terminal holder 3 in a state where the first connection portions 41 are protruded, and are connected to the substrate 2. The housing 5 accommodates the substrate 2 and the terminal holder 3. The conductor unit 6 of the present embodiment is fixed to the terminal holder 3.

The conductor unit 6 includes the first conductor 7 having the frame portion 71 and the plurality of second conductors 8. The first conductor 7 of the present embodiment is fixed to the terminal holder 3. The second conductor 8 has the joint portion 81 joined to the frame portion 71 and the second connection portion 82 connected to a partner terminal. In the electrical junction box 1 of the present embodiment, the plurality of second conductors 8 is joined to the frame portion 71 of the first conductor 7. The second conductors 8 can be freely arranged according to positions of terminals of a connection partner. Therefore, the electrical junction box 1 of the present embodiment has a high degree of freedom in design.

The first conductor 7 of the present embodiment has the substrate connection portion 72 connected to the substrate 2. The plurality of second conductors 8 is connected to the substrate 2 via the substrate connection portion 72. By connecting the plurality of second conductors 8 to the substrate 2 via the substrate connection portion 72, it is possible to simplify the circuit of the substrate 2 and to downsize the substrate 2.

The terminal holder 3 of the present embodiment has the plurality of through holes 31. The terminals 4 are inserted into a part of the through holes 31 among the plurality of through holes 31. The first conductor 7 is fixed to the terminal holder 3 such that the second connection portions 82 are positioned on the extension lines of the other part of the through holes 31 among the plurality of through holes 31. Therefore, in the electrical junction box 1 of the present embodiment, a part of the plurality of arrayed first connection portions 41 can be replaced with the second connection portions 82.

Note that the second conductor 8 is not limited to the terminal for grounding. The second conductor 8 may be a terminal for a power supply, a terminal for a signal, or other terminals. The second conductor 8 may have the plurality of the second connection portions 82. In this case, the plurality of second connection portions 82 is connected to the frame portion 71 by the one joint portion 81. The shape of the connector portion 83 in plan view is not limited to the L shape. The shape of the connector portion 83 is an optional shape that bypasses the first connection portion 41 of the terminal 4.

### First Modification of Embodiment

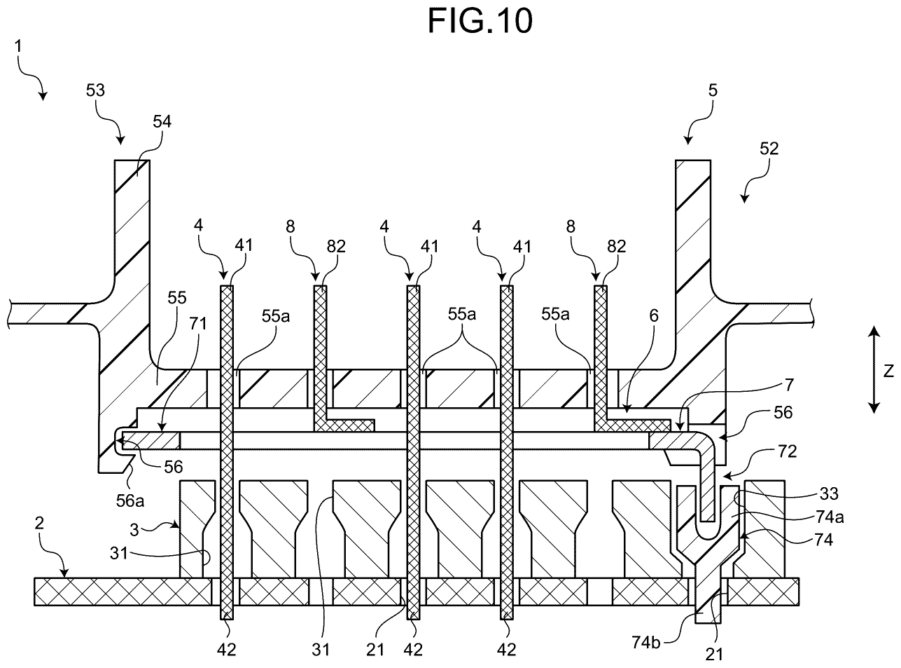

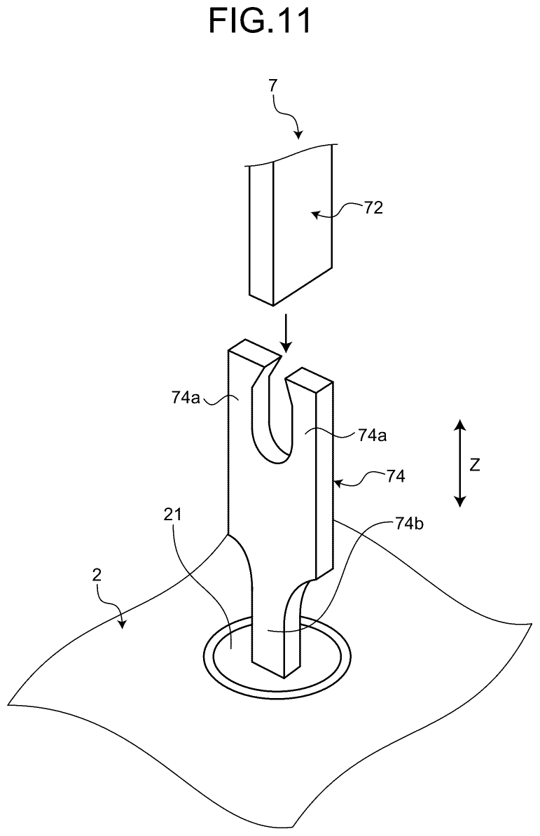

A first modification of the embodiment will be described with reference to FIGS. 10 and 11. FIG. 10 is a cross-sectional view of the electrical junction box according to the first modification of the embodiment, and FIG. 11 is a view illustrating the conductor unit according to the first modification of the embodiment. The electrical junction box 1 illustrated in FIG. 10 is different from the electrical junction box 1 of the above embodiment in that, for example, the first conductor 7 is held by the housing 5.

As illustrated in FIG. 10, the housing 5 according to the first modification of the embodiment has a holding portion 56 that holds the first conductor 7. The exemplified holding portion 56 is provided to the fitting portion 53 of the cover 52. The holding portion 56 is, for example, a groove or a recess into which the outer edge portion of the frame portion 71 is inserted. The holding portion 56 has a claw 56a that locks the frame portion 71. The claw 56a protrudes from an inner side surface of the tube portion 54. The frame portion 71 is engaged with the holding portion 56 along the fitting direction Z, for example. At this time, the second connection portions 82 of the second conductors 8 are inserted into the through holes 55a of the housing 5. The holding portion 56 holds the first conductor 7 so as to position the second connection portions 82 on the extension lines of the through holes 31 of the terminal holder 3. The first conductor 7 held by the holding portion 56 faces the bottom wall 55 of the fitting portion 53 in the fitting direction Z.

Similarly to the electrical junction box 1 of the above embodiment, the terminals 4 are inserted into a part of the through holes 31 among the plurality of through holes 31 of the terminal holder 3. The through holes 31 corresponding to the second connection portions 82 are hollows without any of the terminals 4 being inserted therein.

The conductor unit 6 according to the first modification of the embodiment includes a tuning fork terminal 74. The substrate connection portion 72 is connected to the substrate 2 via the tuning fork terminal 74. The tuning fork terminal 74 is inserted into a holding hole 33 provided in the terminal holder 3 and held by the holding hole 33. The tuning fork terminal 74 has a pair of clamping pieces 74a and a substrate connection portion 74b. The pair of clamping pieces 74a is configured to clamp the substrate connection portion 72 of the first conductor 7. The substrate connection portion 74b is inserted into the through hole 21 of the substrate 2 and soldered to the circuit of the substrate 2.

When the cover 52 is engaged with the main body 51 of the housing 5, the substrate connection portion 72 of the first conductor 7 is inserted between the pair of clamping pieces 74a as illustrated in FIG. 11. As a result, the first conductor 7 is connected to the circuit of the substrate 2 via the tuning fork terminal 74.

### Second Modification of Embodiment

A second modification of the embodiment will be described. The first conductor 7 of the conductor unit 6 does not have to have the substrate connection portion 72. In this case, a joint connector may be connected to the second connection portion 82 of the second conductor 8. In a case where the second conductor 8 is a terminal for grounding, the second conductor 8 is grounded to a body of a vehicle via the joint connector.

The second conductor 8 is not limited to the terminal for grounding. The joint connector connected to the second conductor 8 may connect a power supply line of illumination, may connect a signal line of LIN communication, or may connect other power supply lines or signal lines.

The contents disclosed in the above embodiment and modifications can be appropriately combined and executed.

An electrical junction box according to the present embodiment includes a conductor unit fixed to a terminal holder or a housing, and the conductor unit includes a first conductor that has a frame portion and is fixed to the terminal holder or the housing, and a plurality of second conductors each having a joint portion joined to the frame portion and a second connection portion connected to a partner terminal. According to the electrical junction box according to the present embodiment, it is possible to easily change a position of the second conductor with respect to the frame portion, and an effect that it is possible to improve a degree of freedom in design in arrangement of the terminals is exerted.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. An electrical junction box comprising:
a substrate;
a terminal holder fixed to the substrate;
each of terminals that has a first connection portion connected to a partner terminal, is held by the terminal holder in a state where the first connection portion is protruded, and is connected to the substrate;
a housing that accommodates the substrate and the terminal holder; and
a conductor unit fixed to the terminal holder or the housing, wherein
the conductor unit includes:
a first conductor that has a frame portion and is fixed to the terminal holder or the housing; and
a plurality of second conductors each having a joint portion joined to the frame portion and a second connection portion connected to a partner terminal.

2. The electrical junction box according to claim 1, wherein
the first conductor has a substrate connection portion connected to the substrate, and
the plurality of second conductors is connected to the substrate via the substrate connection portion.

3. The electrical junction box according to claim 1, wherein
the terminal holder has a plurality of through holes, and the terminals are inserted into a part of the through holes among of the plurality of through holes, and
the first conductor is fixed to the terminal holder or the housing such that the second connection portions are positioned on extension lines of the other part of the through holes among the plurality of through holes.

4. The electrical junction box according to claim 2, wherein
the terminal holder has a plurality of through holes, and the terminals are inserted into a part of the through holes among of the plurality of through holes, and
the first conductor is fixed to the terminal holder or the housing such that the second connection portions are positioned on extension lines of the other part of the through holes among the plurality of through holes.
